(19) United States
(12) Patent Application Publication
(10) Pub. No.: US 2006/0204868 A1
(43) Pub. Date: Sep. 14, 2006

(54) Material deposition method and/or system

(76) Inventors: Judson M. Leiser, Corvallis, OR (US); Jeffrey A. Nielsen, Corvallis, OR (US); Steven T. Castle, Philomath, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/075,631

(22) Filed: Mar. 8, 2005

(51) Int. Cl. G03F 7/00

(52) U.S. Cl. 430/30; 430/315; 355/53

(57) ABSTRACT

Embodiments of a method and/or system for material deposition are disclosed.

### TECHNICAL FIELD

The present application is directed to a method and/or system for depositing material.

### BACKGROUND

In a variety of circumstances, it may be desirable to deposit material in a layered fashion. Depending upon the particular context, one difficulty may relate to proper alignment as layers are added over one another. For example, if the layers include patterns, it may be desirable for features of those patterns to be substantially in alignment or for corresponding features of different layers to also be substantially aligned. In this context, the term “dimensional excursions” refers to errors, or distortions, or combinations of both, in a pattern of a deposited layer as a result of processor variations, deformations of a substrate or underlying layers, and/or other sources of error.

### BRIEF DESCRIPTION OF THE DRAWINGS

FIG. 1 is a schematic diagram illustrating an embodiment of a pattern layer deposited with little or no dimensional excursions.

FIG. 2 is a schematic diagram illustrating the embodiment of FIG. 1 with noticeable dimensional excursions.

FIG. 3 is a schematic diagram illustrating a potential result of depositing another pattern layer embodiment over the pattern layer embodiment shown in FIG. 2.

FIG. 4 is a schematic diagram illustrating an embodiment of a sensor capable of detecting features of a pattern layer embodiemt.

FIG. 5 is a schematic diagram illustrating an embodiment of a jetting device.

FIG. 6 is a schematic diagram illustrating an embodiment of a linear encoder.

FIG. 7 is a schematic diagram illustrating an embodiment of a rotary encoder.

FIG. 8 is a schematic diagram illustrating an embodiment of a system for material deposition.

### DETAILED DESCRIPTION

The following detailed description presents illustrative embodiments consistent with claimed subject matter as set forth in this application. This description is not meant to be taken in a limiting sense, but rather to serve the purpose of illustrating general principles consistent with claimed subject matter. In some instances, detailed discussions of various operating components that are not necessary for comprehending claimed subject matter are omitted for simplicity.

As used herein, the term “jetting” refers to any of several material deposition techniques that may be used in the alternative or in combination. For example, U.S. Pat. No. 4,438,191, entitled “Monolithic Ink Jet Print Head,” of Cloutier et al., presents one example of a material deposition mechanism; although claimed subject matter is, of course, not limited to this particular embodiment. A few examples of various types of jetting technologies may include continuous jetting, or piezo-inkjet, or thermal inkjet printing, or combinations thereof. Other deposition techniques may include various dry electrophotography technologies, such as LaserJet® technology, or liquid electrophotography technologies, for example. Claimed subject matter is intended to include all such material deposition techniques. Likewise, examples presented throughout this application are for illustrative purposes only and they are neither exclusive nor meant to limit the scope of claimed subject matter.

Embodiments encompassed by claimed subject matter may include devices, apparatuses, systems, methods, and/or other subject matter that may be employed to substantially align material deposited as a pattern layer, or a portion thereof, over a previous pattern layer or portion thereof. In some embodiments, as discussed in more detail hereinafter, accomplishing such alignment may involve addressing dimensional excursions and/or other variations that may exist in a pattern layer. In this particular context, the term pattern layer refers to a layer of material that has been deposited so as to form a pattern. Typically, such pattern layers are deposited on or over a substrate or another pattern layer, although, of course, claimed subject matter is not limited in scope in this respect.

In describing embodiments, reference herein may be made to “depositing a pattern layer,” or the like. An embodiment may effect the deposition of a pattern layer by depositing material so as to form a pattern. The phrase “depositing a pattern layer,” or the like, may be used herein to refer to such a process for purposes of simplifying the disclosure.

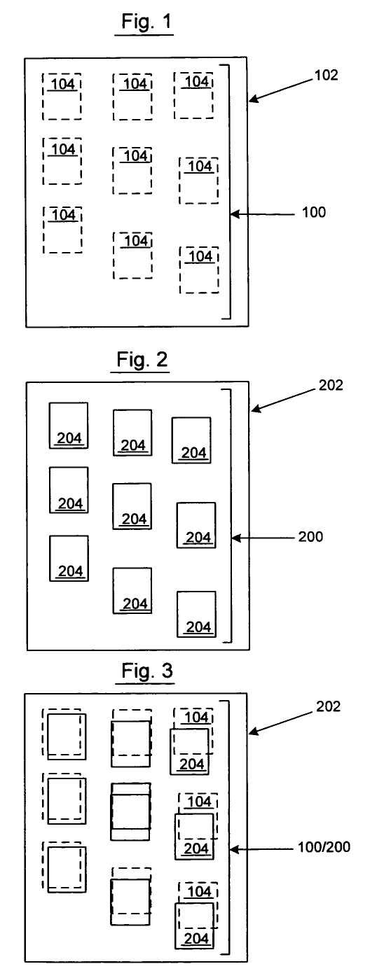

FIG. 1 is a schematic diagram illustrating an embodiment 100 of a pattern layer that has been deposited on a substrate 102, although claimed subject matter is not limited in scope in this respect. Pattern layer 100 comprises, in this embodiment, a plurality of structures 104. For simplicity, structures 104 are illustrated as rectangles in FIG. 1. However, in alternate embodiments any geometrical or combination of geometrical shapes may be utilized. Because structures 104 are repeated within composite pattern layer 100, structures 104 also illustrate a repeated pattern, or sub-pattern, of composite pattern layer 100. Other more complex structures may also be included in pattern layer 100.

Features of pattern layer 100 or features of structures 104 may be selected for subsequent detection, or identification or both. For example, substantially perpendicular or parallel borders or edges of structures 104 may be selected and/or defined as features identifying composite pattern layer 100 and/or structures 104. Similarly, ribs or spaces between structures 104, or both may be selected as detectable features. Material corresponding to one or more additional pattern layers may be deposited in substantial alignment with pattern layer 100. In this particular context, the term substantial alignment or substantially aligned refers to the notion that corresponding features are substantially spatially aligned in a particular direction. For example, between pattern layers, particular corresponding features of dfferent pattern layers may be substantially aligned vertically, although this example is not intended to limit the scope of claimed subject matter. As described in more detail hereinafter, as an example, one embodiment may employ a sensor or one or more other feature detection mechanisms to detect one or more features of a pattern layer. Based, at least in part, on the features detected, material may be deposited to form another or subsequent pattern layer having features that may correspond to and be substantially aligned with the detected features, although claimed subject matter is not limited in scope in this respect.

In one embodiment, pattern layers are deposited in substantially vertical alignment. Substantially vertically aligning layers of deposited material may be achieved by depositing material for a pattern layer over a prior pattern layer, such as pattern layer 100, for example. Subsequent layers may, therefore, be substantially aligned with respect to position, size, orientation, or relative placement, or combinations thereof over pattern layer 100, for example. Other parameters for substantially aligning layers may also be used. For example, layers may be substantially aligned based at least in part on feature-by-feature matching between layers, such as, for example, based at least in part on structures, such as 104. In such an embodiment, detection of a feature in pattern layer 100, for example, such as structures 104, for example, by a sensor and/or through other detection mechanisms may be used to trigger the deposition of material to comprise a corresponding feature in a subsequent layer, so that a feature in the subsequent layer may be substantially vertically aligned with the corresponding detected feature. Any one of a number of techniques may be employed to trigger such deposition and claimed subject matter is not limited in scope to a particular approach or technique.

Likewise, in an alternate embodiment, material may be deposited in substantial horizontal alignment. For example, if pattern layer 100 covers a portion of substrate 102, an additional composite pattern layer portion and/or one or more additional structures 104 may be depositied in a substantially adjacent and/or substantially horizontally aligned relationship. For pattern layer 100, for example, substantially horizontal alignment may include depositing a subsequent layer or structures 104 so as to substantially align rows or columns or both on substantially the same layer. Alternative alignments, or variations or combinations thereof may be employed as well.

FIG. 2 is a schematic diagram illustrating a pattern layer embodiment, here 200, in which noticeable dimensional excursions have occurred. As embodied in FIG. 2, pattern layer 200 includes structures 204 that exhibit distortions relative to structures 104 of FIG. 1, for example. The distortions in pattern layer 200 may result from dimensional excursions potentially due, at least in part, to defects in substrate 202, or variations, or errors, or both introduced during the process by which pattern layer 200 was deposited. Alternative or additional sources of error may also lead to distortion in pattern layer 200.

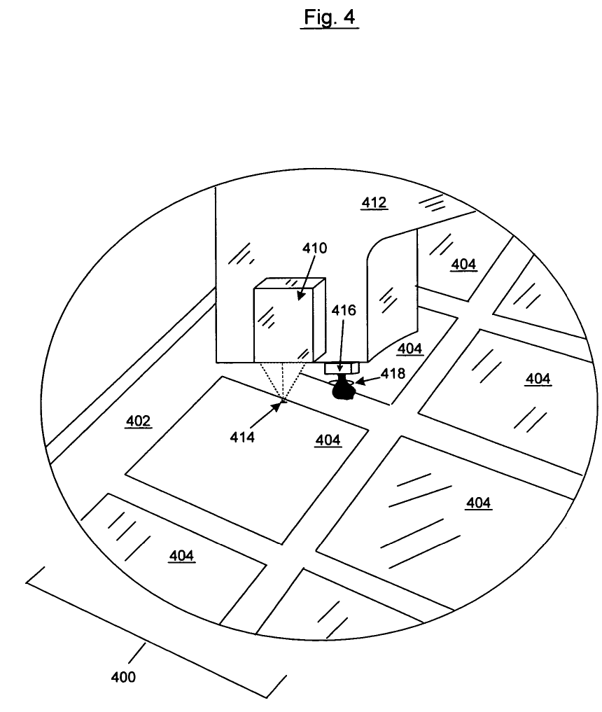

FIG. 3 is a schematic diagram illustrating that dimensional excursions in a pattern layer may affect deposition of material in a subsequent pattern layer. More particularly, FIG. 3 illustrates a lack of alignment that may occur if pattern layer 200 of FIG. 2 were deposited over pattern layer 100 of FIG. 1. The layered patterns of FIG. 3 show mismatches such as pattern size, orientation, or alignment, combinations thereof, for example. Other types of mismatches may also occur between pattern layers, depending, at least in part, on the type of errors or distortions, or both, that may be present in a pattern layer over which a subsequent pattern layer is to be deposited.

Embodiments within the scope of claimed subject matter may at least partially compensate such mismatches, or distortions, or errors, or combinations thereof, by triggering the deposition of material for a subsequent layer based at least in part on detecting selected features of a previous or prior pattern layer. The previous pattern layer may comprise a layer deposited across at least a portion of a substrate, or it may comprise one or more smaller structures and/or repeated patterns. Many other pattern types or variations may also exist within the scope of claimed subject matter. Deposition may be substantially synchronized, or controlled, or both using, in part, position information or other feedback, or both obtained from detecting one or more features of a pattern layer. Information regarding such features may be gathered as part of the process of depositing material to form a subsequent layer, referred to in this context, as “real-time.” Information on dimensional excursions, for example exhibited by features of a previous pattern layer may then be used, at least in part, to provide timing information, or other control signals, or both when depositing material to form a subsequent pattern layer.

One embodiment may employ a sensor mechanism to detect, or evaluate, or various combinations thereof the features of a pattern layer. Some examples of possible sensors, listed for illustrative purposes only and not as a limitation on claimed subject matter, may include laser profilometers, laser displacement sensors, or retro-reflective LDC sensors, or various combinations of sensors, to name a few. Other suitable variations may be used as well and are also within the scope of claimed subject matter. An alternative embodiment may employ a vision system using a charge coupling device (“CCD”) video camera and frame grabber, or other imaging devices, to obtain information regarding a previous pattern layer.

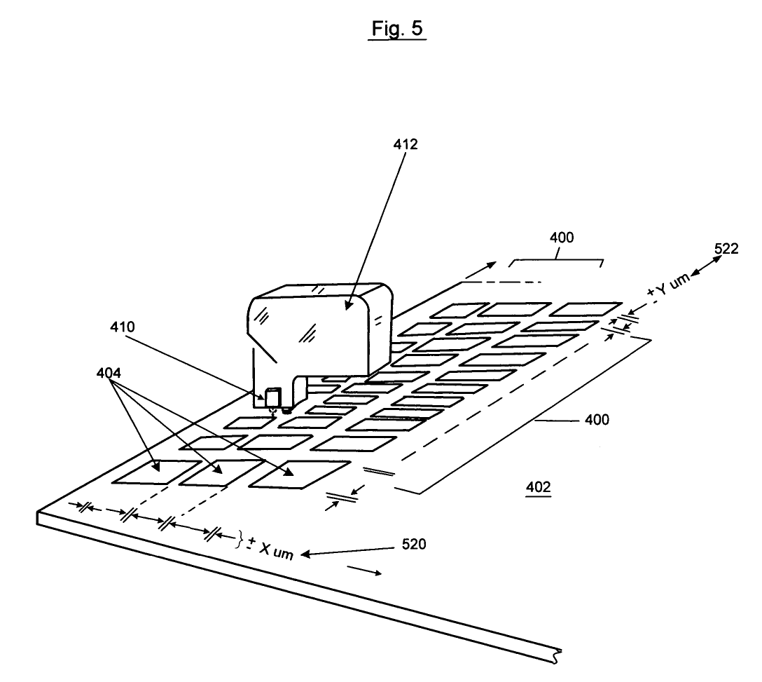

FIGS. 4 and 5 present an embodiment of a sensor for detecting features of a pattern layer. FIG. 4 depicts a detailed, close-up view of the sensor embodiment illustrated in FIG. 5. With particular reference to FIG. 4, movement of sensor 410 may be to translate substantially proximate to a previously deposited pattern layer. As sensor 410 translates over pattern layer 400, in this example, sensor 410 detects features within the pattern layer, such as feature 414, which is illustratively embodied, in one example, as the edge of one of structures 404 within pattern 400. In one embodiment, sensor 410 may be coupled to a jetting device or other deposition mechanism 412 having a nozzle 416 or other device for depositing material 418 for creating one or more additional layers. Of course, such an embodiment is but one possible configuration, and many alternative and/or additional implementations may be employed within the scope of claimed subject matter.

As shown in the embodiment illustrated in FIG. 5, pattern layer 400 may present a fairly sizable layer relative to substrate 402 (e.g., pattern layer 400 may extend substantially across substrate 402). Pattern layer 400 also illustrates dimensional excursions among and between pattern layer structures 404, for example. Indications 520 and 522 in FIG. 5 illustrate one or more potentially cumulative dimensional excursions that may result in a pattern layer, such as pattern layer 400, in this embodiment. For example, factors such as variations and/or errors in the deposition process, distortions in the substrate as a result of the introduction of thermal and/or physical stress, as well as other factors, may result in dimensional excursions such as spacing variations and/or other size, position, or orientation variations, or various combinations thereof, being introduced between structures 404 of pattern layer 400. Incremental dimensional excursions among structures 404 may aggregate or otherwise combine to produce a potentially cumulative dimensional excursion over the length of pattern layer 400. This potentially may result in a relatively larger displacement of structures 404. Of course, dimensional excursions need not be cumulative. Consistent with claimed subject matter, they also may exhibit substantially random or unpredictable characteristics that may at least partially offset one another, or they may exhibit other features or characteristics or both in addition or in the alternative to those presented herein.

As shown in FIGS. 4 and 5, embodiments consistent with claimed subject matter may accommodate dimensional excursions by depositing material in subsequent pattern layers based at least in part on variations evidenced through the sensing of one or more features in a previous pattern layer. With particular reference to the embodiment of FIG. 4, as sensor 410 detects feature 414, there being an applicable offset between deposition mechanism nozzle 416, at area 418, and sensor 410, as well as having information such as position, velocity, acceleration, or other positioning information, or various combinations thereof relating the deposition mechanism to the detected feature 414 in pattern layer 400, may allow timing, or other control signals or both to direct the deposition of material corresponding to another pattern layer to be deposited in substantial alignment with pattern layer 400.

In one embodiment, an encoder may be employed as one method for ascertaining position information. A sensor affixed or otherwise coupled with the deposition mechanism may be configured such that a typical incremental encoder signal may be obtained based, at least in part, on the features in the pattern layer deposited on the substrate. Encoder calculations may be used to obtain substantially accurate position information corresponding to sensed features.

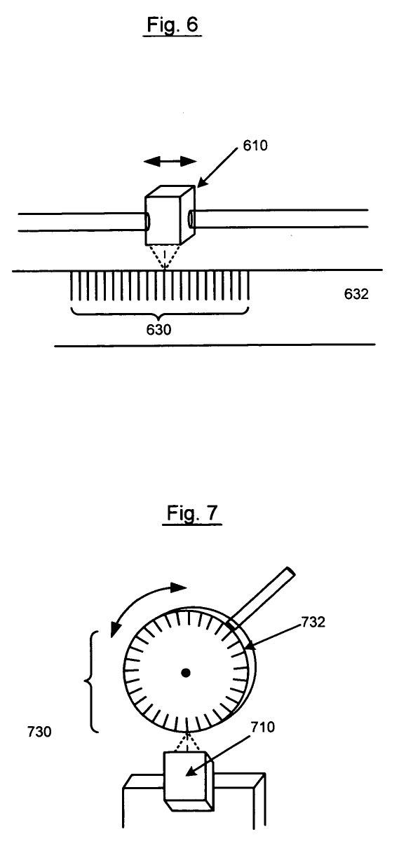

FIG. 6 illustrates one example of an encoder strip 632 having a series of marks 630 that may be detected by a sensor 610 coupled with (or otherwise incorporating the functionality of) a linear encoder. As sensor 610 travels over encoder strip 632, the linear encoder may obtain position information based, at least in part, on the sensing of marks 630 located at known distance references.

As an alternative to the embodiment of FIG. 6, the embodiment of FIG. 7 depicts a sensor that includes a rotary encoder. Analogous to encoder strip 632 of FIG. 6, FIG. 7 includes a plate 732 with a series of marks 730 that pass sensor 710 as plate 732 rotates. Although FIG. 7 illustrates a sensor incorporating a rotary encoder in an embodiment implementing a plate design, this is but one example of a rotary encoder. An alternative type of rotary encoder may embody a cylindrical design, for example, in which marks are positioned along a surface of a rotating cylinder, the rotation of which may result in marks to pass a sensor for detection.

Various types and models of encoder devices are commercially available and may be implemented, with or without configuration changes or other adaptations or modifications, as desirable, for embodiments consistent with claimed subject matter. For example, the following technical data specifications and data sheets provide specific detail on various encoders: “Agilent AEAS-7000 Plug and Play Ultra-Precision Absolute Encoder 16-bit Gray Code,” Feb. 23, 2004, Agilent Technologies, Inc.; “Reflective Optical Surface Mount Encoders,” Feb. 19, 2004, Agilent Technologies, Inc.; “Agilent HEDS-9710, HEDS-9711 200 Ipi Analog Output Small Optical Encoder Modules,” May 10, 2002, Agilent Technologies, Inc.; and “Agilent ADNS-2051 Optical Mouse Sensor,” Oct. 8, 2004, Agilent Technologies, Inc. Of course, claimed subject matter is not limited to employing these or any other particular encoders.

Consistent with claimed subject matter, incremental encoders conceptually similar to the embodiments illustrated in FIGS. 6 and 7 may be employed physically, functionally, or otherwise coupled with a deposition mechanism, or various combinations thereof. Thus, such embodiments may use one or more features identifiable in a pattern layer effectively as an encoder strip, for example, providing positioning information that may be used to synchronize, or align, or both deposited material with a previously deposited layer.

In another potential embodiment, encoder embodiments may use pattern features. Depending at least in part on the particular embodiment, such features may be substantially uniform in appearance, frequency, spacing, or other characteristics, or various combinations thereof, or such features may not be substantially uniform. Such encoders may be used, for example, to obtain relative, or incremental position information, or both. By employing substantially uniform features as marks, a feature detected by the sensor may convey incremental position information relative to a previous feature detected by the sensor.

However, in another embodiment, substantially non-uniform features may be slightly different in a discernable, or quantifiable fashion, or both such that they may be used in concert with a sensor system. In such an embodiment, an encoder may also obtain, from such detected features, desired position information.

Pattern features may be pre-selected based at least in part on the type of material and/or pattern layer being deposited. One example may be embodied in an application for depositing red/green/blue color filter material onto LCD displays. The color filters may be conceptualized, for illustrative purposes, as small substantially rectangular structures, analogous to structures 104 of FIG. 1. The ribs between color wells (e.g., the rectangular color filter cutouts) may be designated as features providing positioning information to an encoder. Edges of a rectangular portion may also be selected or used, as may many other features that may be detected by a sensor.

Many alternative embodiments are also possible. For example, in another embodiment, gate lines leading to a transistor element may be used as pattern features to trigger deposition of semiconductor material at a corresponding location. In still another embodiment, color transitions, such as from black to gray sections of a substrate, or between red, green, and blue rectangles in an LCD display, could be designated as pattern features detectable using color-sensitive sensors. Many other pattern feature selections may also be made based at least in part on the desired application.

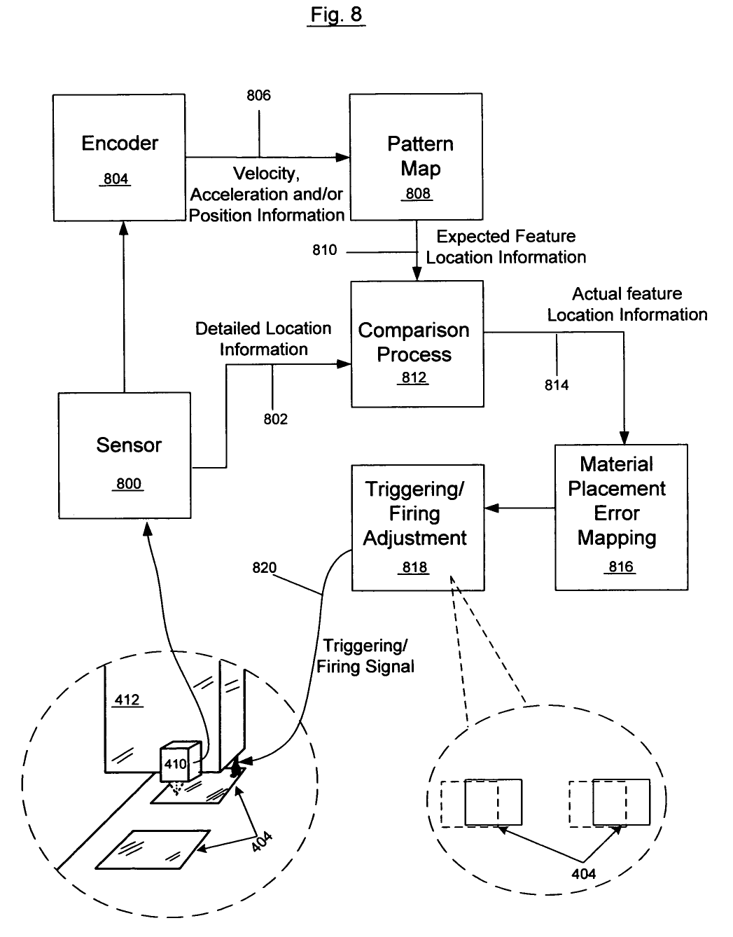

FIG. 8 presents one example of a process flow diagram embodying elements of a system for aligning pattern layers. In one embodiment, communications to, or from, or between elements of FIG. 8 or various combinations thereof may be controlled, at least in part, by one or more processors, controllers, programs, routines, computerized devices, or other control mechanisms or various combinations, to mention but a few examples.

With particular reference to FIG. 8, an embodiment of a system for depositing material is illustrated. A sensor 800 may obtain substantially detailed location information 802 for features detected within a pattern layer. An encoder 804 may map the location, or velocity, or acceleration, or other position, or timing information, or various combinations based at least in part on a Cartesian, or spherical, or cylindrical or other coordinate encoder system including combinations of encoder systems. Encoder 804 may gather information 806 regarding the depositing mechanism's velocity, or acceleration, or position, or combinations and convey it for use with a pattern map 808 representing a desired pattern substantially without dimensional excursions. Pattern map 808 may provide expected feature location information 810 to be used in a comparison process 812. Comparison process 812 may also use detailed location information 802 and provide actual feature location information 814 to generate a material-placement error mapping 816. Error mapping 816 may be used to determine an appropriate triggering or firing adjustment 818 (e.g., in terms of distance, timing, and/or other parameters), which may result in a firing or triggering signal 820 being sent to a deposition mechanism's nozzle, or other deposition device, so that the subsequent pattern layer material may be deposited in substantial alignment with a prior pattern layer.

Many changes may be made to the details of the above-described embodiments without departing from the scope of claimed subject matter. All such changes that fall within the scope of the following claims are intended to be covered by the following claims.

1. An apparatus, comprising:
a sensor to detect one or more features of a first pattern layer; and
a deposition mechanism configured to deposit material for a second pattern layer based at least in part on said one or more features.

2. The apparatus of claim 1 wherein said deposition mechanism is configured to deposit said material over said first pattern layer in substantial alignment with said one or more features.

3. The apparatus of claim 1, wherein said one or more features are selected for detection.

4. The apparatus of claim 1, wherein said sensor includes an encoder configured to determine position information from detection of said one or more features.

5. The apparatus of claim 4, wherein said deposition mechanism is further configured to deposit said material based at least in part on said position information.

6. The apparatus of claim 1, wherein said one or more features comprises a plurality of features.

7. An apparatus, comprising:
a sensor to detect one or more features of a pattern layer over a substrate;
an encoder configured to determine position information based at least in part on said one or more detected features; and
a deposition mechanism configured to deposit material corresponding to a next pattern layer based at least in part on said position information.

8. The apparatus of claim 7, wherein said deposition mechanism is configured to trigger deposition of material over said pattern layer.

9. The apparatus of claim 8, wherein said deposition mechanism is configured to trigger said deposition of material such that said next pattern layer is substantially aligned with said pattern layer over said substrate.

10. The apparatus of claim 7, wherein said deposition mechanism is configured to deposit material so that said one or more features of said pattern layer is substantially aligned with one or more corresponding features in said next pattern layer.

11. A system, comprising:
a sensor configured to detect a plurality of features in a current pattern layer;
an encoder configured to determine position information based at least in part on said plurality of features; and
a deposition mechanism configured to deposit material substantially in response to the position information determined by said encoder, said material deposited corresponding to a next pattern layer in substantial alignment with said current pattern layer.

12. The system of claim 11, wherein said plurality of features are pre-selected.

13. The system of claim 11, wherein said next pattern layer is substantially aligned over said current pattern layer.

14. The system of claim 11, wherein said plurality of features are substantially uniform.

15. A method, comprising:
detecting a feature in a current pattern layer; and
depositing material for a corresponding feature in a next pattern layer such that said corresponding feature is aligned with said feature in said current pattern layer.

16. The method of claim 15, wherein said feature in said current pattern layer is pre-selected to be detected.

17. The method of claim 15, further comprising:
determining position information for said feature in said current pattern layer;
wherein said material is deposited based at least in part on said position information.

18. The method of claim 17, wherein said determining position information includes detecting said feature with an encoder.

19. The method of claim 15, further comprising:
determining position information for said feature; and
comparing said position information to a pattern map to determine one or more dimensional excursions in said current pattern layer;
wherein depositing includes depositing so that said corresponding feature is substantially aligned based at least in part on said one or more dimensional excursions.

20. A method for aligning layered patterns on a substrate, said method comprising:
detecting a pattern layer over a substrate;
signaling deposition of material for another pattern layer based at least in part on said pattern layer over said substrate.

21. The method of claim 20, wherein said detecting includes sensing one or more features of said pattern layer.

22. The method of claim 21, further comprising depositing said another pattern layer in substantial alignment with said pattern layer over said substrate.

23. The method of claim 22, wherein depositing said another pattern layer includes aligning said another pattern layer at least in part based on one ore more dimensional excursions of said pattern layer over said substrate.

24. The method of claim 20, wherein said signaling deposition includes conveying timing information.

25. A method for depositing a subsequent pattern layer in substantial alignment with a previous pattern layer, said method comprising:
sensing a feature in said previous pattern layer;
determining one or more dimensional excursions in said previous pattern layer based at least in part on the sensed feature; and
depositing said subsequent layer so that said one or more dimensional excursions applies to a corresponding feature in said subsequent pattern layer.

26. The method of claim 25, wherein said determining said one or more dimensional excursions includes comparing the sensed feature to a representative feature in a pattern map.

27. A system for depositing a pattern layer, comprising:
means for sensing a previous pattern layer;
means for determining dimensional excursions in said previous pattern layer; and
means for depositing a next pattern layer substantially in alignment with said dimensional excursions in said previous pattern layer.

28. The system of claim 27, said means for depositing comprising means for signaling the deposit of said next pattern layer.

29. A substrate having a plurality of substantially aligned pattern layers constructed by the process of:
determining dimensional excursions in a first pattern layer; and
in response to determining said dimensional excursions, depositing a next pattern layer so as to incorporate said dimensional excursions into said next pattern layer.

30. The substrate of claim 29, wherein the process further includes depositing said next pattern layer so as to substantially align said next pattern layer with said first pattern layer.

31. The substrate of claim 29, wherein said determining dimensional excursions includes obtaining positioning information for one or more features of said first pattern layer.

32. The substrate of claim 31, wherein said obtaining positioning information includes sensing said one or more features with an encoder.
